(19) United States
(12) Patent Application Publication
(10) Pub. No.: US 2026/0314150 A1
(43) Pub. Date: Oct. 8, 2026

(54) DISPLAY DEVICE

(71) Applicant: QISDA CORPORATION, Taoyuan City (TW)

(72) Inventors: PO-FU WU, Taoyuan City (TW); TSUNG-HSUN WU, Taoyuan City (TW)

(21) Appl. No.: 19/567,241

(22) Filed: Mar. 15, 2026

(30) Foreign Application Priority Data
Apr. 7, 2025 (CN) 202510425386.9

(51) Int. Cl. H10H 29/85; H10H 29/24

(52) U.S. Cl. CPC H10H 29/857; H10H 29/24

(57) ABSTRACT

A display device includes an active light-emitting package and a plurality of passive light-emitting packages. The active light-emitting package includes a light-emitting driver chip and at least one first light-emitting element electrically connected to the light-emitting driver chip. The plurality of passive light-emitting packages are electrically connected to the active light-emitting package, and each of the plurality of passive light-emitting packages includes at least one second light-emitting element. The light-emitting driver chip is configured to drive the at least one first light-emitting element and each of the second light-emitting elements.

### CROSS-REFERENCE TO RELATED PATENT APPLICATION

This application claims the benefit of priority to China Patent Application No. 202510425386.9, filed on Apr. 7, 2025, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a display device, and more particularly to a display device having high assembly flexibility, high repairability, and high reliability.

### BACKGROUND OF THE DISCLOSURE

In direct-view LED (DVLED) display applications, a complete display system is usually composed of multiple light boards, in which each of the pixels contains LED chips in at least three colors, and the number of three-color LED chips on each of the light boards can reach hundreds of thousands to millions. These LED chips require a driving circuit to control the brightness and switching of the LED.

In the above-mentioned display applications, driving manners can be divided into centralized driving and decentralized driving. For example, in existing DVLEDs using centralized driving, a single driving circuit can control 1920 LEDs through matrix scanning (taking 16 scanning lines and 120 channels as an example), and the 1920 LEDs can form 640 pixels. The advantage of centralized driving is that the number of driving ICs is small; however, the wiring is complicated, and the failure of a single LED may cause other LEDs on the same scanning line to be constantly lit, which causes the commonly known caterpillar phenomenon to occur. Although the use of decentralized driving can reduce the number of wirings and prevent the occurrence of the caterpillar phenomenon, decentralized driving will increase the number of driving circuits required.

In addition, both centralized and decentralized drive architectures are prone to be affected by wiring complexity and LED failures, and spacings between the pixels of the product is fixed and difficult to adjust, thus affecting material preparation and cost control.

Therefore, it is necessary to design a new type of display device to overcome the above-mentioned problems.

### SUMMARY OF THE DISCLOSURE

In response to the above-referenced technical inadequacies, the present disclosure provides a display device. The display device has good repairability and reliability for assembling pixel structure, and can reduce material cost.

In order to solve the above-mentioned problems, one of the technical aspects adopted by the present disclosure is to provide a display device. The display device includes an active light-emitting package and a plurality of passive light-emitting packages. The active light-emitting package includes a light-emitting driver chip and at least one first light-emitting element. The at least one first light-emitting element is electrically connected to the light-emitting driver chip. The plurality of passive light-emitting packages are connected to the active light-emitting package. Each of the plurality of passive light-emitting packages includes at least one second light-emitting element. The light-emitting driver chip is configured to drive the at least one first light-emitting element and each of the second light-emitting elements.

Therefore, compared to existing technologies, in the display device provided by the present disclosure, by the design of the active light-emitting package respectively driving the first light-emitting element and the plurality of second light-emitting elements, the occurrence of the caterpillar phenomenon can be avoided when a single light-emitting element fails. Furthermore, spacings between any two light-emitting elements or spacings between pixels formed by a plurality of light-emitting elements can be freely adjusted according to practical requirements with a high degree of customization flexibility, thereby overcoming the limitation of fixed spacing. In addition, in the display device provided in the present disclosure, the active light-emitting package can be arbitrarily arranged and combined with a plurality of non-driven passive light-emitting packages at a pixel position to form a desired spacing shape or cluster size, such that users can freely assemble pixel structures according to practical requirements, thereby allowing the display device to have good repairability and reliability for assembling pixel structure, and reducing material cost.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a functional block diagram of a display device according to one embodiment of the present disclosure;

FIG. 2 is a schematic exploded view of components of a display panel according to one embodiment of the present disclosure;

FIG. 3 is a top view of a plurality of light panel modules after being assembled according to one embodiment of the present disclosure;

FIG. 4 is a top view of one of the light panel modules according to one embodiment of the present disclosure;

FIG. 5 is another top view of one of the light panel modules according to one embodiment of the present disclosure;

FIG. 6 is yet another top view of one of the light panel modules according to one embodiment of the present disclosure;

FIG. 7 is still another top view of one of the light panel modules according to one embodiment of the present disclosure; and

FIG. 8 is still another top view of one of the light panel modules according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

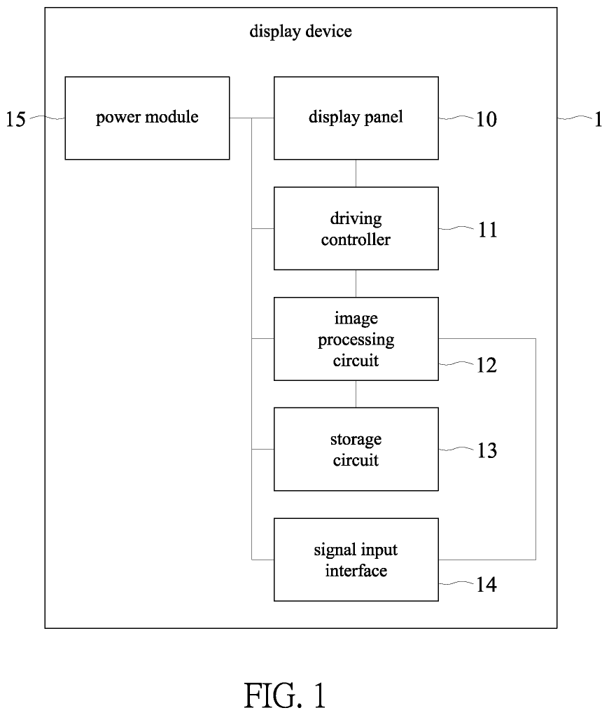

FIG. 1 is a functional block diagram of a display device according to one embodiment of the present disclosure. Referring to FIG. 1, a display device 1 is provided in one embodiment of the present disclosure. The display device 1 may be a direct view light-emitting diode (DVLED) display commonly used in large advertising billboards. As shown in FIG. 1, the display device 1 may include components such as a display panel 10, a driving controller 11, an image processing circuit 12, a storage circuit 13, a signal input interface 14, and a power module 15. The power module 15 may be a power supply including a power converter for providing a stable voltage required for the display panel 10, the driving controller 11, the image processing circuit 12, the storage circuit 13, and the signal input interface 14.

The signal input interface 14 is electrically connected to the image processing circuit 12, the image processing circuit 12 is electrically connected to the storage circuit 13 and the driving controller 11, and the driving controller 11 is electrically connected to the display panel 10.

The signal input interface 14 may be an HDMI®, a DisplayPort™, or a DVI interface module for allowing external image signal to be input via the signal input interface 14. For example, the signal input interface 14 may receive input signals from a computer, a media player, or an image transmission device. The signal input interface 14 may also support a variety of image formats, such as HDMI®, DisplayPort™, DVI, SDI, and USB type-C.

The storage circuit 13 can be used to store the firmware and/or software required for the operation of the display device 1, as well as display configuration parameters (such as color calibration data and brightness correspondence curve). In certain embodiments, the storage circuit 13 can further store image playback content to provide an offline playback function. The storage circuit 13 may be a NAND cache memory, an electrically-erasable programmable read-only memory (EEPROM), and an SD or eMMC memory module.

The image processing circuit 12 is mainly responsible for processing and transmitting image signals. For example, the image processing circuit 12 can receive video data from the signal input interface 14 and transmit processed image data to the driving controller 11. The image processing circuit 12 can also access image data or parameters in the storage circuit 13. The image processing circuit 12 can be used to adjust the resolution, frame synchronization, color correction, HDR processing, grayscale adjustment, flicker removal, multi-screen splicing, and seamless border correction of the image signal to improve the display quality.

The driving controller 11 can receive the data signal from the image processing circuit 12 and convert the data signal into LED driving signal. For example, the driving controller 11 can control the LED brightness through pulse width modulation (PWM) or current regulation technology. In one example, the driving controller 11 can select a suitable way of driving, such as static driving or dynamic scanning driving, according to the dot pitch and refresh rate of the display panel 10. The driving controller 11 is further configured to analyze the image signal, convert the image signal into displayable data, and control the display mode of the display panel 10.

The display panel 10 may be a light-emitting display panel, in which each of the pixels may include at least one light-emitting element, such that each of the pixels can emit light by itself. Therefore, unlike a liquid crystal display (LCD) device, since components such as a backlight unit or a liquid crystal layer are not required in the present disclosure, a smaller thickness of the display device can be achieved, and various design changes can be made due to the simple structure.

In addition, the display panel 10 may use micro light-emitting diodes (microLEDs) as light-emitting elements disposed in each of the pixels. By using microLEDs, a pixel size may be reduced and a higher resolution may be achieved within a screen of a same size.

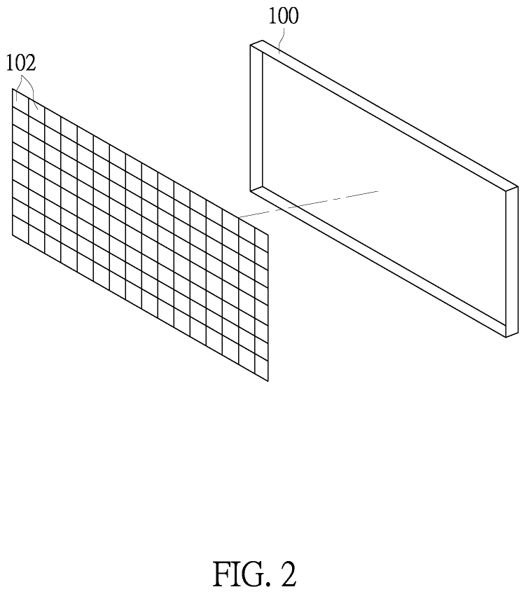

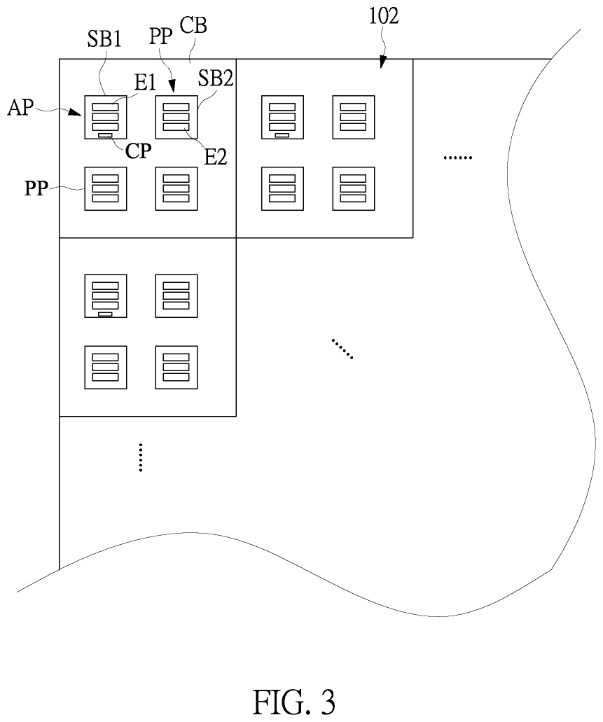

FIG. 2 is a schematic exploded view of components of a display panel according to one embodiment of the present disclosure, and FIG. 3 is a top view of a plurality of light panel modules after being assembled according to one embodiment of the present disclosure. As shown in FIGS. 2 and 3, the display panel 10 may include a housing 100 and a plurality of light panel modules 102. The plurality of light panel modules 102 may be assembled with each other in the form of a two-dimensional matrix, and the housing 100 may be used to support the plurality of light panel modules 102. However, embodiments of the display panel 10 are not limited thereto. As an example, the display panel 10 may be formed by a single light panel module 102. In certain embodiments, the light panel modules 102 may be magnetically or mechanically coupled to each other, or bonded to each other by an adhesive, and installed in the housing 100. Components such as the driving controller 11, the image processing circuit 12, the storage circuit 13, the signal input interface 14, and the power module 15 may also be disposed in the housing 100.

The light panel module 102 may include a circuit substrate CB, and an active light-emitting package AP and a plurality of passive light-emitting packages PP disposed on the circuit substrate CB. For example, the active light-emitting package AP and the plurality of passive light-emitting packages PP may be disposed on the circuit substrate CB to form one of the light panel modules 102. In certain embodiments, the light panel module 102 may also include a plurality of the active light-emitting packages AP and the plurality of passive light-emitting packages PP.

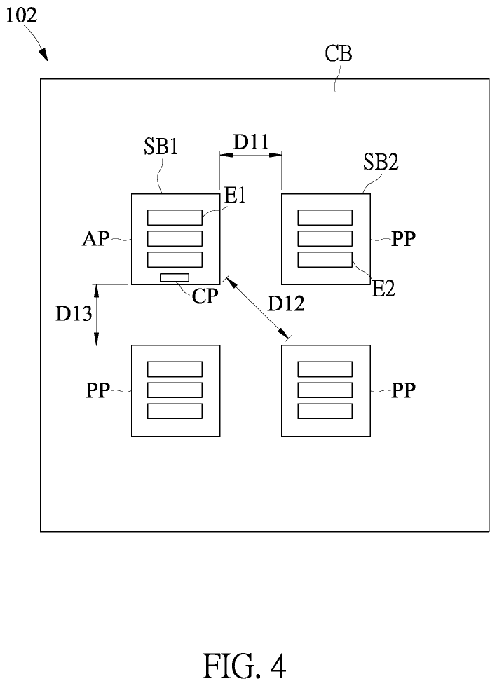

FIG. 4 is a top view of one of the light panel modules according to one embodiment of the present disclosure. Referring to FIG. 4, the active light-emitting package AP may include a light-emitting driver chip CP and at least one first light-emitting element E1 electrically connected to the light-emitting driver chip CP. In certain embodiments, a tri-color light-emitting diode (LED) chip of red (R), green (G), and blue (B) colors may be directly soldered on a printed circuit board (PCB) through surface mount technology (SMT) to serve as a pixel that can emit light independently and mix different colors, thereby achieving high-density full-color display.

In addition, the active light-emitting package AP can also integrate multiple microLEDs into a single package through the microLED in package (MiP) technology. Alternatively, the active light-emitting package AP can also integrate multiple groups of RGB LED units into one package unit through the integrated matrix device (IMD) technology. In other words, multiple pixels can be directly integrated into one package unit to increase pixel density.

In the active light-emitting package AP, the light-emitting driver chip CP and the at least one first light-emitting element E1 electrically connected to the light-emitting driver chip CP can be disposed on a packaging substrate SB1 that is such as a ceramic substrate or an FR4 substrate. The active light-emitting package AP can further have a plurality of contacts (for example, solder pads) formed on the packaging substrate SB1, and the light-emitting driver chip CP, the first light-emitting element E1, and the plurality of contacts can be formed on the same side or different sides of the packaging substrate SB1. A number of the plurality of contacts of the active light-emitting package AP is greater than or equal to a number of the plurality of passive light-emitting packages PP. In addition, a surface of the packaging substrate SB1 on which the first light-emitting element E1 and the light-emitting driver chip CP are disposed can be further covered by silicone or epoxy resin that serve as a protective layer to improve reliability and durability.

The passive light-emitting packages PP are electrically connected to the active light-emitting package AP, and each of the passive light-emitting packages PP includes at least one second light-emitting element E2. Similarly, in each of the passive light-emitting packages PP, the tri-color LED chip of R, G, and B colors can be directly soldered on the PCB through SMT, and multiple microLED chips are integrated into a single package through MiP technology, or multiple RGB LED units are integrated into one package unit through IMD technology.

In each of the passive light-emitting packages PP, at least one second light-emitting element E2 can be disposed on a packaging substrate SB2 that is such as a ceramic substrate or an FR4 substrate. Each of the passive light-emitting packages PP further has a plurality of contacts (for example, solder pads) formed on the packaging substrate SB2, and the second light-emitting element E2 and the plurality of contacts can be formed on the same side or different sides of the packaging substrate SB2.

Taking FIG. 4 as an example, when the active light-emitting package AP and the passive light-emitting packages PP are disposed on the circuit substrate CB, the plurality of passive light-emitting packages PP can be coupled to the plurality of contacts of the active light-emitting package AP through a plurality of circuit traces of the circuit substrate CB.

It should be noted that, a light-emitting driver chip CP having corresponding driving capabilities can be selected for the active light-emitting package AP according to the number of the first light-emitting element E1 and the second light-emitting element E2 to be driven. The light-emitting driver chip CP may include a constant current driving circuit (e.g., a current source circuit), a dimming control circuit, a power management circuit, a grayscale control circuit, a communication interface, and a protection circuit. The constant current driving circuit can provide a stable current to the first light-emitting element E1 and the second light-emitting element E2 that are driven to ensure uniform brightness. The dimming control circuit can control the brightness, color, and contrast of the LED through pulse width modulation (PWM) dimming technology. The power management circuit is electrically connected to the power module 15, and can be a buck, boost, or buck-boost type power converter circuit for providing a suitable voltage to the first light-emitting element E1 and the second light-emitting element E2 that are driven. The grayscale control circuit can perform grayscale control through grayscale current regulation technology to enhance the color layering for the first light-emitting element E1 and the second light-emitting element E2 that are driven. The communication interface may be a serial communication interface that is used to provide communication capability between the light-emitting driver chip CP and the driving controller 11, and allow the brightness, color, and mode to be configured through the driving controller 11. The protection circuit may include one or more of an overvoltage protection circuit, an overcurrent protection circuit, and a thermal protection circuit to ensure that the first light-emitting element E1 and the second light-emitting element E2 that are driven can operate stably for a long time to prevent abnormal conditions such as overheating, overcurrent, and short circuit from occurring.

As shown in FIG. 4, in this embodiment, each of the light panel modules 102 may include a predetermined number of passive light-emitting packages PP. For example, the light panel module 102 may include three of the passive light-emitting packages PP, but the number of passive light-emitting packages PP in each of the light panel modules 102 may be the same or different. For example, in at least one light panel module 102 disposed at the edge of the display panel 10, the number of passive light-emitting packages PP may be different from the number of passive light-emitting packages PP in the light panel modules 102 not disposed at the edge.

As shown in FIG. 4, the passive light-emitting packages PP are disposed to surround the active light-emitting package AP. Since the total number of the active light-emitting package AP and the passive light-emitting package PP is four, they can be arranged to form a two-by-two array. The active light-emitting package AP can be spaced apart from the three passive light-emitting packages PP by multiple distances D11, D12, and D13, respectively; at least a portion of the distances are equal to each other. For example, the distances D11 and D13 are equal, but the distance D12 is different from the distances D11 and D13. In certain embodiments, the active light-emitting package AP and the passive light-emitting package PP can be arranged to form a square matrix, that is, to form an array having an equal number of columns and rows. In addition, the active light-emitting package AP includes at least three contacts coupled to the passive light-emitting packages PP and at least one contact electrically connected to the driving controller 11.

Furthermore, the light-emitting driver chip CP of the active light-emitting package AP can be used to drive the second light-emitting elements E2 of the three passive light-emitting packages PP to emit light. Through this configuration, the design and manufacturing efficiency can be improved due to the small number of circuits and simple wiring. In addition, since the active light-emitting package AP drives each of the first light-emitting element E1 and multiple light-emitting elements E2, the caterpillar phenomenon can be avoided when a single light-emitting element fails. Furthermore, the spacing between two light-emitting elements or the spacing of pixels formed by multiple light-emitting elements can be freely adjusted according to practical requirements with a high degree of customization flexibility, thereby overcoming the limitation of fixed spacing.

In addition, in the display device 1 of the present disclosure, the active light-emitting package AP can be arbitrarily arranged and combined with multiple non-driven passive light-emitting packages PP at positions of pixels to form a required pitch shape or cluster size according to wiring characteristics of different types of circuit substrates CB (for example, a fixed-pitch contact configuration such as that of a breadboard), allowing users to freely assemble the pixel structure according to practical requirements, such that the display device has good repairability and reliability, and can reduce material cost.

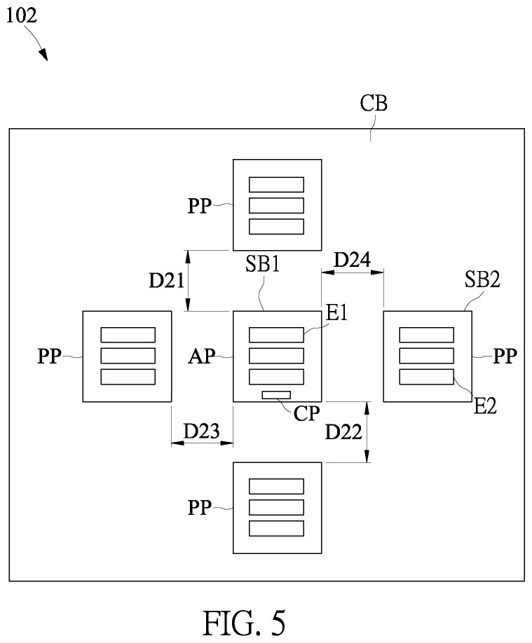

FIG. 5 is another top view of one of the light panel modules according to one embodiment of the present disclosure. Referring to FIG. 5, in another implementation, the passive light-emitting packages PP are disposed to surround the active light-emitting package AP, the number of the passive light-emitting packages PP is four, and the passive light-emitting packages PP are arranged in a cross-shape together with the active light-emitting package AP. For example, the four passive light-emitting packages PP can be respectively disposed on an upper side, a lower side, a left side, and a right side of the active light-emitting package AP, and are respectively spaced apart from the active light-emitting package AP by distances D21, D22, D23, and D24. At least a portion of the distances D21, D22, D23, and D24 are equal to each other. Taking this embodiment as an example, the distances D21, D22, D23, and D24 are equal to each other. In addition, the active light-emitting package AP includes at least four contacts coupled to the passive light-emitting packages PP and one contact electrically connected to the driving controller 11.

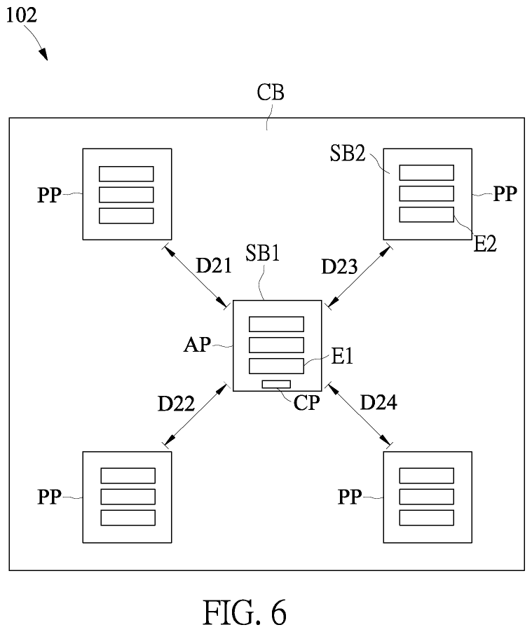

FIG. 6 is yet another top view of one of the light panel modules according to one embodiment of the present disclosure. Referring to FIG. 6, the passive light-emitting package PP and the active light-emitting package AP can be arranged in another manner to form a cross. For example, four passive light-emitting packages PP can be respectively disposed at an upper-left side, a lower-left side, and upper-right side, and a lower-right side of the active light-emitting package AP, and are respectively spaced apart from the active light-emitting package AP by distances D21, D22, D23, and D24. At least a portion of the distances D21, D22, D23, and D24 are equal to each other. Taking this embodiment as an example, the distances D21, D22, D23, and D24 are equal to each other.

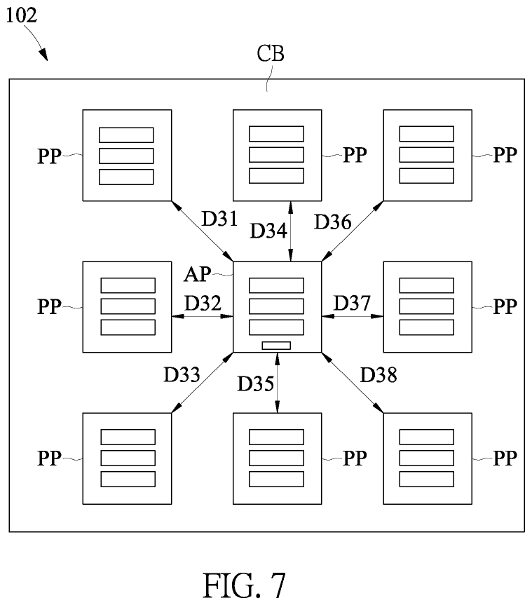

FIG. 7 is still another top view of one of the light panel modules according to one embodiment of the present disclosure. Referring to FIG. 7, in another implementation, the passive light-emitting packages PP are disposed to surround the active light-emitting package AP, the number of the passive light-emitting packages PP is eight, and the passive light-emitting package PP are arranged together with the active light-emitting package AP to form a three-by-three array. For example, the eight passive light-emitting packages PP can be respectively disposed at the upper-left side, the left side, the lower-left side, the upper side, the lower side, the upper-right side, the right side, and the lower-right side of the active light-emitting package AP, and are respectively spaced apart from the active light-emitting package AP by distances D31, D32, D33, D34, D35, D36, D37, and D38. At least a portion of the distances D31, D32, D33, D34, D35, D36, D37, and D38 are equal to each other. Taking this embodiment as an example, the distances D31, D33, D36, and D38 are equal to each other, and the distances D32, D34, D35, and D37 are equal to each other, but the distances D31, D33, D36, and D38 are different from the distances D32, D34, D35, and D37.

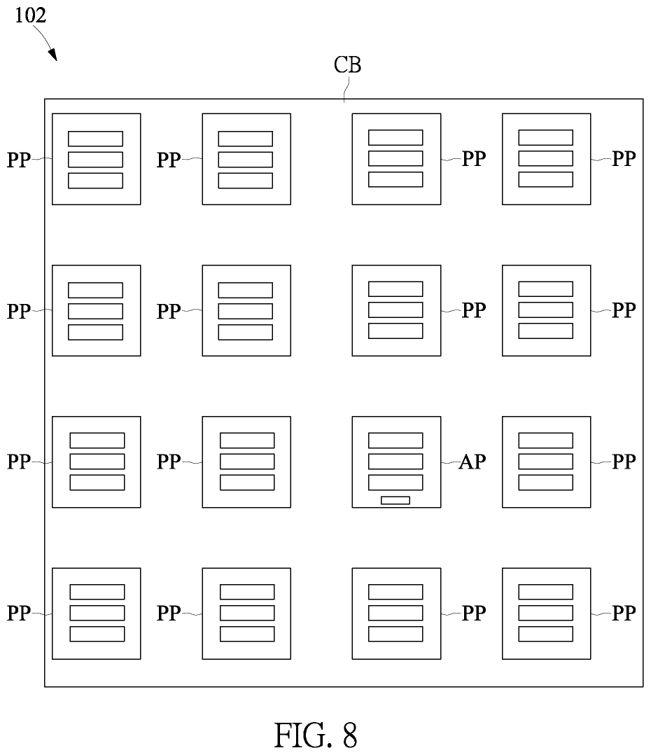

FIG. 8 is still another top view of one of the light panel modules according to one embodiment of the present disclosure. Referring to FIG. 8, in another implementation, the passive light-emitting packages PP are disposed to surround the active light-emitting package AP, the number of the passive light-emitting package PP is fifteen, and the passive light-emitting packages PP are arranged together with the active light-emitting package AP to form a four-by-four array. Similar to the aforementioned embodiments, the spacing between two light-emitting elements in the four-by-four array can be arbitrarily determined according to practical requirements. It should be noted that, the user can select one or more of the light panel modules 102 of FIGS. 4 to 8 above for combination according to practical requirements, so as to arbitrarily arrange and combine the active light-emitting package AP and a plurality of non-driven passive light-emitting packages PP at the pixel position to form a desired spacing shape or cluster size, and freely assemble the pixel structure.

In conclusion, the display device provided by the present disclosure includes an active light-emitting package and a plurality of passive light-emitting packages, and the active light-emitting package includes a light-emitting driver chip and at least one first light-emitting element electrically connected to the light-emitting driver chip. The plurality of passive light-emitting packages are electrically connected to the active light-emitting package, and each of the plurality of passive light-emitting packages includes at least one second light-emitting element. The light-emitting driver chip is configured to drive each first light-emitting element and each of the second light-emitting elements. Since the active light-emitting package can respectively drive the first light-emitting element and the plurality of second light-emitting elements, the occurrence of the caterpillar phenomenon can be avoided when a single light-emitting element fails. Furthermore, spacings between any two light-emitting elements or spacings between pixels formed by a plurality of light-emitting elements can be freely adjusted according to practical requirements with a high degree of customization flexibility, thereby overcoming the limitation of fixed spacing. In addition, in the display device provided in the present disclosure, the active light-emitting package can be arbitrarily arranged and combined with a plurality of non-driven passive light-emitting packages at a pixel position to form a desired spacing shape or cluster size, such that users can freely assemble pixel structures according to practical requirements, thereby allowing the display device to have good repairability and reliability for assembling pixel structure, and reducing material cost.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A display device, comprising:
an active light-emitting package, including:
a light-emitting driver chip; and
at least one first light-emitting element electrically connected to the light-emitting driver chip; and
a plurality of passive light-emitting packages electrically connected to the active light-emitting package, wherein each of the plurality of passive light-emitting packages includes at least one second light-emitting element;
wherein the light-emitting driver chip is configured to drive the at least one first light-emitting element and each of the second light-emitting elements.

2. The display device according to claim 1, wherein the active light-emitting package has a plurality of contacts, and the light-emitting driver chip is electrically connected to the plurality of passive light-emitting packages through the plurality of contacts.

3. The display device according to claim 2, wherein a number of the plurality of contacts is greater than or equal to a number of the plurality of passive light-emitting packages.

4. The display device according to claim 2, wherein the active light-emitting package and the plurality of passive light-emitting packages are disposed on a circuit substrate to form a light panel module, and the circuit substrate includes a plurality of circuit traces for respectively coupling the plurality of passive light-emitting packages to the plurality of contacts.

5. The display device according to claim 4, wherein the plurality of passive light-emitting packages are respectively spaced apart from the active light-emitting package by a plurality of predetermined distances, and at least a portion of the plurality of predetermined distances are equal to each other.

6. The display device according to claim 4, further comprising multiple ones of the light panel module that are connected to each other.

7. The display device according to claim 6, wherein each of the light panel modules includes a predetermined number of the plurality of passive light-emitting packages, and the predetermined numbers of at least a portion of the plurality of light panel modules are different.

8. The display device according to claim 7, wherein the plurality of passive light-emitting packages are disposed to surround the active light-emitting package, a number of the plurality of passive light-emitting packages is three, and the passive light-emitting packages are arranged together with the active light-emitting package to form a two-by-two array.

9. The display device according to claim 8, wherein the three passive light-emitting packages are respectively spaced apart from the active light-emitting package by a plurality of distances equal to each other.

10. The display device according to claim 7, wherein the plurality of passive light-emitting packages are disposed to surround the active light-emitting package, a number of the plurality of passive light-emitting packages is four, and the passive light-emitting packages are arranged together with the active light-emitting package to form a cross.

11. The display device according to claim 10, wherein the four passive light-emitting packages are respectively disposed at an upper side, a lower side, a left side, and a right side of the active light-emitting package.

12. The display device according to claim 11, wherein the four passive light-emitting packages are respectively spaced apart from the active light-emitting package by a plurality of distances equal to each other.

13. The display device according to claim 10, wherein the four passive light-emitting packages are respectively disposed at an upper-left side, a lower-left side, an upper-right side, and a lower-right side of the active light-emitting package.

14. The display device according to claim 13, wherein the four passive light-emitting packages are respectively spaced apart from the active light-emitting package by a plurality of distances equal to each other.

15. The display device according to claim 7, wherein the plurality of passive light-emitting packages are disposed to surround the active light-emitting package, a number of the plurality of passive light-emitting packages is eight, and the passive light-emitting packages are arranged together with the active light-emitting package to form a three-by-three array.

16. The display device according to claim 15, wherein the eight passive light-emitting packages are respectively disposed at an upper-left side, a left side, a lower-left side, an upper side, a lower side, an upper-right side, a right side, and a lower-right side of the active light-emitting package.

17. The display device according to claim 16, wherein the four passive light-emitting packages disposed at the upper-left side, the lower-left side, the upper-right side, and the lower-right side of the active light-emitting package are respectively spaced apart from the active light-emitting package by a plurality of first distances that are equal to each another, the four passive light-emitting packages disposed at the left side, the upper side, the lower side, and the right side of the active light-emitting package are respectively spaced apart from the active light-emitting package by a plurality of second distances that are equal to each another, and the plurality of first distances are different from the plurality of second distances.

18. The display device according to claim 7, wherein the plurality of passive light-emitting packages are disposed to surround the active light-emitting package, the number of the plurality of passive light-emitting packages is fifteen, and the passive light-emitting packages are arranged together with the active light-emitting package to form a four-by-four array.

19. The display device according to claim 7, further comprising a display panel, wherein a number of the passive light-emitting packages disposed in the light panel modules disposed at an edge of the display panel is different from a number of the passive light-emitting packages disposed in the light panel modules not disposed at the edge of the display panel.

20. The display device according to claim 7, wherein the active light-emitting package at least includes the plurality of contacts coupled to the plurality of passive light-emitting packages and at least one contact electrically connected to a driving controller.
